(19) United States
(12) Patent Application Publication
(10) Pub. No.: US 2024/0046134 A1
(43) Pub. Date: Feb. 8, 2024

(54) SPIN QUBIT ELECTRONIC DEVICE

(71) Applicant: COMMISSARIAT A L'ENERGIE ATOMIQUE ET AUX ENERGIES ALTERNATIVES, Paris (FR)

(72) Inventors: Xavier BAILLIN, Grenoble Cedex 09 (FR); Richard FOURNEL, Grenoble Cedex 09 (FR)

(73) Assignee: COMMISSARIAT A L'ENERGIE ATOMIQUE ET AUX ENERGIES ALTERNATIVES, Paris (FR)

(21) Appl. No.: 18/336,169

(22) Filed: Jun. 16, 2023

(30) Foreign Application Priority Data
Jun. 23, 2022 (FR) 22 06266

(51) Int. Cl. G06N 10/40

(52) U.S. Cl. CPC G06N 10/40

(57) ABSTRACT

An electronic device includes first and second quantum dots disposed along a direction, first and second control gates associated with said quantum dots, and a magnet configured to generate two opposite spin states at each of the first and second quantum dots. The magnet includes first and second magnetic domains distributed along the direction and separated by a domain wall. The magnetic domains respectively have first and second magnetisations of opposite directions in the direction. The first and second quantum dots thus receive first and second magnetic field gradients.

### TECHNICAL FIELD

The present invention relates to the field of quantum electronics. It has a particularly advantageous application in producing quantum bit or qubit quantum devices, making it possible to perform quantum calculations and/or binary logic operations.

### STATE OF THE ART

In the field of quantum electronics, a quantum bit or qubit corresponds to a quantum state which represents the smallest unit of quantum information storage. This quantum state is characterised by the quantum superposition of several states, in particular of state 0 and of state 1. In practice, the quantum bit or qubit can be obtained by different devices based on different architectures. Thus, there are qubits linked to a quantum state:
of a charge carrier, for example the spin of an electron (spin qubit),
of a current circulating between two supraconductive regions through a Josephson junction, for example its phase (supraconductive qubit),
of a trapped ion or an atom or a molecule, for example its energy level,
of a photon, for example its bias (photonic qubit).

Each type of device has intrinsic advantages and distinct disadvantages. For example, supraconductive qubit quantum devices make it possible to obtain a good entanglement between qubits. The error rate in the quantum calculation from supraconductive qubits is low. However, these supraconductive qubits require a cryogenised environment. Controlling supraconductive qubits is complex and expensive.

Spin qubit quantum devices, on the contrary, a low entanglement. Their energy consumption in operation is low, and their manufacture is facilitated by microelectronic methods. These spin qubit quantum devices constitute one of the most promising ways in developing quantum processors.

It is possible to handle the spin state (top and bottom) of the qubits by the electron spin resonance (ESR) technique. Under the action of a magnetic field, two distinct energy levels corresponding to two opposite spin states appear by Zeeman effect. Thus, by exposing the qubit to a radiofrequency (RF) radiation, it is possible to shift the qubit from one spin state to another, typically coding for 0 and 1.

A challenge linked to quantum calculation is being able to individually handle these spin qubits. A way of distinguishing qubits from one another consists of allocating to them different spin resonance frequencies. Controlling the spin state of these different qubits can thus be done by applying substantially different radio frequencies.

Document US 2010270534 A1 discloses different configurations of spin qubit devices making it possible to individually control the qubits. In particular, these devices comprise a ferromagnetic magnet producing a magnetic field gradient at the qubits. The intensity of the resulting magnetic field is thus modified locally according to the positions of the qubits. The energy levels, and the corresponding resonance frequency are therefore different from one qubit to another. The individual controlling of the qubits is thus made possible. It is however necessary to provide a sufficiently large separation distance between the qubits to be able to distinguish them. This limits the integration density of the spin qubits. Moreover, the use of a permanent magnet rather than a magnetic field induced by a coil does not make it possible to change the configuration of the spin qubit device. These devices are not therefore reprogrammable to perform other logic operations, for example.

An aim of the present invention is to overcome these disadvantages.

In particular, an aim of the present invention is to propose a spin qubit device enabling the individual controlling of qubits in an improved manner. Another aim of the present invention is to propose a spin qubit device enabling an increase integration density. Another aim of the present invention is to propose a spin qubit device which could be reinitialised or reconfigured.

Another aim of the present invention is to propose a method for producing these quantum devices.

The other aims, features and advantages of the present invention will appear upon examining the description below and the accompanying drawings. It is understood that other advantages can be incorporated.

### SUMMARY

To achieve this aim, according to an embodiment, an electronic device is provided, comprising at least:
one first quantum dot and one second quantum dot disposed along a longitudinal direction, configured to each have two opposite spin states, in the presence of an external magnetic field,
one first control gate associated with the first quantum dot,
one second control gate associated with the second quantum dot,
one magnet configured to locally generate a magnetic field gradient between the first and second quantum dots, such that the first and second quantum dots respectively have first and second resonance frequencies which are different from one another.

Advantageously, the magnet comprises at least one first magnetic domain and one second magnetic domain distributed along the longitudinal direction and separated by at least one domain wall.

These first and second magnetic domains respectively have a first magnetisation and a second magnetisation in opposite directions in the longitudinal direction, so as to locally generate said magnetic field gradient between the first and second quantum dots. The first and second quantum dots (Qdots) receive a magnetic field resulting from the external magnetic field and from the magnetic field of the magnet, and thus have first and second resonance frequencies which are different from one another, due to the magnetic field gradient generated by the magnet.

The external magnetic field is substantially uniform, in amplitude and in direction. Its intensity is typically around 1 Tesla (T). This corresponds to the “macroscopic” component of the magnetic field received by the quantum dots. The magnetic field generated by the magnet has local variations in intensity and of in directions, thanks to the different magnetic domains of the magnet. This corresponds to the “microscopic” component of the magnetic field received by the quantum dots. Its intensity is typically around ten or a few tens of milliTesla (mT). Each quantum dot therefore receives the superposition of the macroscopic and microscopic components of the resulting magnetic field. The modulation according to the longitudinal direction of the magnetic field produced by the magnet, generates a microscopic component which alternatively takes different amplitude values for each of the first and second quantum dots. This results, advantageously, in that the first and second quantum dots have first and second resonance frequencies which are different from one another.

The opposite magnetisations of the two magnetic domains make it possible to increase the magnetic field gradient between the quantum dots. Thus, the resonance frequencies enabling the first and second quantum dots to pass from one spin state to another are significantly different. The first and second quantum dots can therefore be controlled individually. This increase in magnetic field gradient advantageously makes it possible to increase the integration density of the quantum dots, while preserving a good control of the spin state of each of the quantum dots.

According to an option, the wall(s) separating the magnetic domains of the magnet can be moved, in particular by applying an electric current within the magnet in the longitudinal direction. This advantageously makes it possible to reconfigure the device and to modify the control parameters of the spin qubit device. The device is therefore reprogrammable.

According to an aspect, a system is provided, comprising at least one electronic device such as described, the system being taken from among: a computer or a quantum accelerator, or a quantum router.

According to an aspect of the invention, a method for producing such an electronic device is provided, comprising at least the following steps:
Forming the first and second quantum dots,
Forming the first and second control gates associated with said first and second quantum dots,
Forming the magnet by carrying out at least the following steps:
   Depositing a ferromagnetic material,
   Moving the domain wall within the ferromagnetic material so as to form the first and second magnetic domains, by applying an electric current along the longitudinal direction.

### BRIEF DESCRIPTION OF THE FIGURES

The aims, objectives, as well as the features and advantages of the invention will best emerge from the detailed description of embodiments of the latter which are illustrated by the following accompanying drawings, wherein:

FIG. 1 illustrates the fluctuations of the components Bx and Bz of the magnetic field induced by the magnetic domains of the magnet according to an embodiment of the present invention.

FIG. 2A schematically illustrates, as a cross-section, an electronic device according to a first embodiment of the present invention.

FIG. 2B schematically illustrates, as a top view, the electronic device illustrated in FIG. 2A.

FIG. 3A schematically illustrates, as a cross-section, an electronic device, according to a second embodiment of the present invention.

FIG. 3B schematically illustrates, as a top view, the electronic device illustrated in FIG. 3A.

FIG. 4A schematically illustrates, as a cross-section, an electronic device, according to a third embodiment of the present invention.

FIG. 4B schematically illustrates, as a top view, the electronic device illustrated in FIG. 4A.

FIG. 5 schematically illustrates, as a top view, an electronic device according to a fourth embodiment of the present invention.

FIG. 6 schematically illustrates an electronic device according to an embodiment of the present invention.

FIG. 7 schematically illustrates an electronic device according to another embodiment of the present invention.

FIG. 8 schematically illustrates, as a top view, a strip comprising notches intended to fix the domain walls, according to an embodiment of the present invention.

The drawings are given as examples, and are not limiting of the invention. They constitute principle schematic representations intended to facilitate the understanding of the invention, and are not necessarily to the scale of practical applications. In particular, on the principle diagrams, the dimensions of the different elements and layers are not necessarily representative of reality.

### DETAILED DESCRIPTION

Before starting a detailed review of embodiments of the invention, optional features are stated below, which can optionally be used in association or alternatively:

According to an example, the magnet comprises a plurality of first and second magnetic domains distributed along the longitudinal direction, alternated from one another, and separated by a plurality of domain walls, the device further comprising a plurality of quantum dots distributed along the longitudinal direction and a plurality of control gates associated with said quantum dots. According to an example, the number of quantum dots is related to the number of magnetic domains. Thus, each quantum dot can be associated with a distinct magnetic domain. Alternatively, several quantum dots can be associated with one same magnetic domain. This makes it possible to design different architectures for controlling individual quantum dots or groups of quantum dots. According to a particular architecture, the device comprises N quantum dots and the magnet comprises N magnetic domains separated by N−1 walls. Each quantum dot corresponds to a magnetic domain in this configuration. According to another particular architecture, the device comprises N quantum dots and the magnet comprises N walls separating N+1 magnetic domains. Each quantum dot corresponds to a wall in this configuration. According to another architecture, the device comprises N quantum dots and the magnet comprises M magnetic domains separated by M−1 walls. One or more quantum dots correspond to one same magnetic domain in this configuration. In this configuration, for example, two adjacent quantum dots can face magnetic domains or walls in the same magnetisation direction.

According to an example, two adjacent quantum dots of the plurality of quantum dots are separated by a distance L in the longitudinal direction, preferably L≤200 nm. According to an example, the magnetic domains have a dimension n·L in the longitudinal direction, with n a non-zero natural integer, typically of between 1 and N−M+1. The dimension of the magnetic domains corresponds, in this case, substantially to a multiple of the distance separating two adjacent quantum dots. This makes it possible to obtain periodic or pseudo-periodic magnetic field fluctuations having a period proportional or identical to that of the arrangement of the quantum dots along the longitudinal direction. This makes it possible to dispose the quantum dots corresponding to the strongest magnetic field variations. According to an option, the magnetic domains have variable dimensions n·L along the longitudinal direction. The distribution of magnetic domains of different dimensions is not therefore periodical along the longitudinal direction, but this distribution remains correlated to the arrangement of the quantum dots. A magnetic domain of dimension 3L can thus correspond to 3 quantum dots. This magnetic domain can be followed in the longitudinal direction by another magnetic domain of dimension L, corresponding to 1 quantum dot. Thus, the magnetic domains of dimension nL preferably correspond to n quantum dots.

According to an example, the magnet is presented in the form of a strip and the domain wall is transversally fixed to the strip by notches at the edges of the strip. The strip preferably has a dimension in the longitudinal direction, greater, and preferably a lot greater than the dimensions transverse to the longitudinal direction. Thus, a strip substantially corresponding to a slab of dimensions Lx in the longitudinal direction, Ly and Lz in directions of a plane transverse to the longitudinal direction, is preferably sized such that 1≤Ly/Lx≤3 and Lz≈0.2.Lx. The domain wall typically extends mainly along a plane transverse to the longitudinal direction, by being fixed or blocked in the strip by the notches formed on either side of the strip. The notches typically form a narrowing of the cross-section of the strip. They can be rectangular, for example of dimensions nₓ of between 15 and 30 nm, and n_{y} between 10% and 20% of Lx. The notches advantageously make it possible to control the positions of the domain walls.

According to an example, the magnet is presented in the form of a strip and the at least one domain wall is transversally fixed to the strip by a discontinuous variation of cross-section of the strip. A sudden narrowing or expansion of the width of the strip can thus enable the fixing of a domain wall.

According to an example, the strip is Fe-, Co-, Ni-, or B-based, or alloys of these metals, for example CoFe or Ni₈₀Fe₂₀ or CoFeB. The ferromagnetic material of the magnet or of the strip is not however limited to this choice of metals or alloys.

According to an example, the device further comprises a domain wall generator at the border of the magnet. This makes it possible, if necessary, to generate or regenerate domain walls within the magnet. Such a wall generator can be presented in the form of a ferromagnetic material-based injection structure, of wide dimensions contiguous to one of the ends of the magnet or of the strip. Such a structure is, for example, described in the document, “R. P. Cowburn, Journal of Applied Physics 91, 6949 (2002)”.

According to an example, the device comprises N quantum dots occupying N positions P1 to P_{N} distributed along the longitudinal direction, N gates associated with said N quantum dots, and the magnet comprises N+1 magnetic domains having opposite alternating magnetisations and separated by N domain walls, said N walls comprising to respectively N planes transverse to the longitudinal direction passing through the positions P1 to P_{N} of the N quantum dots. In this embodiment, the domain walls can be substantially located in vertical alignment with the quantum dots. The quantum dots are not disposed facing the magnetic domains, they are located facing the walls separating said magnetic domains, i.e. at an x-axis Xn=nL with n=1 . . . N, for quantum dots regularly separated by a distance L in the longitudinal direction. In this embodiment, the quantum dots are subjected to a maximum gradient of the component Bz of the magnetic field generated by the magnet.

According to an example, the device comprises N quantum dots regularly separated by a distance L in the longitudinal direction, N gates associated with said N quantum dots, and the magnet comprises N magnetic domains of dimension substantially equal to L in the longitudinal direction, having opposite alternating magnetisations and separated by N−1 domain walls, said N quantum dots being distributed along the longitudinal direction facing and corresponding to the N magnetic domains, each quantum dot occupying, in the longitudinal direction, a position of between L/2 and L vis-à-vis an end of the corresponding magnetic domain, advantageously a position located at 3/4L vis-à-vis an end of the corresponding magnetic domain.

According to an example, the device comprises N quantum dots regularly separated by a distance L in the longitudinal direction, N gates associated with said N quantum dots, and the magnet comprises N magnetic domains of dimension substantially equal to L in the longitudinal direction, having opposite alternating magnetisations and separated by N−1 domain walls, said N quantum dots being distributed along the longitudinal direction facing and corresponding to N magnetic domains, each quantum dot occupying, in the longitudinal direction, a position substantially located at 314L vis-à-vis an end of the corresponding magnetic domain. In this embodiment, the quantum dots are disposed facing magnetic domains, at 314L from the edge of each magnetic domain in the longitudinal direction, i.e. at an x-axis Xn=314L+(n−1)L, with n=1 . . . N. In this embodiment, the quantum dots are subjected to a maximum gradient of the sum of the components Bx+Bz of the magnetic field generated by the magnet.

According to an example, the device comprises N quantum dots regularly separated by a distance L in the longitudinal direction, N gates associated with said N quantum dots, and wherein the magnet comprises N magnetic domains of dimension substantially equal to L in the longitudinal direction, having opposite alternating magnetisations and separated by N−1 domain walls, said N quantum dots being distributed along the longitudinal direction facing and corresponding to N magnetic domains, each quantum dot occupying, in the to longitudinal direction, a position substantially located at L/2 vis-à-vis an end of the corresponding magnetic domain. In this embodiment, the quantum dots are disposed facing magnetic domains, at L/2 from the edge of each magnetic domain in the longitudinal direction, i.e. at an x-axis Xn=L/2+(n−1)L, with n=1 . . . N. In this embodiment, the quantum dots are subjected to a maximum gradient of the component Bx of the magnetic field generated by the magnet.

According to an example, the device comprises at least one first line and one second line, parallel to one another, and directed in the longitudinal direction, each line comprising at least two quantum dots and two control gates, each respectively associated with one of said quantum dots, the device further comprising at least one first magnet and one second magnet, respectively associated with the first and second lines, each magnet comprising at least the first and second magnetic domains distributed along the longitudinal direction and separated by a domain wall, said first and second magnetic domains respectively having the first and second magnetisations of opposite directions in the longitudinal direction, the first magnet being disposed parallel to the first line and the second magnet being disposed parallel to the second line, so as to locally generate a first magnetic field gradient between the first and second quantum dots of the first line, and a second magnetic field gradient between the first and second quantum dots of the second line. In this embodiment, the quantum dots are distributed in a matrix, in lines and columns. Magnets, each comprising a plurality of magnetic domains distributed in the longitudinal direction and having opposite, alternating magnetisations, are associated with each of the lines of quantum dots. In the presence of the external magnetic field, each quantum dot has two opposite spin states, by Zeeman effect. For each line, the associated magnet produces a magnetic field, locally varying at the quantum dots of said line. It is therefore possible to configure the magnets of the different lines, such that adjacent quantum dots, taken in the lines and the columns, have resonance frequencies which are different from one another. The spin state of each quantum dot can thus be controlled individually by a control gate associated with said quantum dot. According to an option, the control gates are disposed along the columns of the matrix of quantum dots. The device thus makes it possible to individually control the quantum dots of a matrix of quantum dots.

According to an example, the first and second magnetisations of the first and second magnetic domains of the first magnet respectively have the same direction as the first and second magnetisations of the first and second magnetic domains of the second magnet, at the same positions in the longitudinal direction along the first and second lines. The first and second magnets thus have, substantially side-by-side, the same magnetic field distribution. This makes it possible to avoid a potential field compensation coming from the first magnet by the second magnet. This makes it possible to maximise the field fluctuations along the first and second lines.

According to an example, the first and second magnetisations of the first and second magnetic domains of the first magnet respectively have an opposite direction to the second and first magnetisations of the second and first magnetic domains of the second magnet, at the same positions in the longitudinal direction along the second lines. The first and second magnets thus have, side-by-side, magnetic domains substantially in phase opposition. This makes it possible to differentiate the resonance frequency of a given qubit vis-à-vis the resonance frequencies of the qubits closest to being in the vicinity of this qubit.

According to an example, one same line can comprise one or more magnet strips parallel to one another and having the same magnetisation fields. This makes it possible to reinforce the local magnetic field created by the magnet. The quantum dots can thus be farther away from the magnet. This makes it possible to increase the number of possible configurations for the arrangement and the placement of the quantum dots vis-à-vis the magnet.

According to an example, the method for producing the device further comprises, before the movement of the domain wall, a generation of at least one domain wall within the ferromagnetic material. This generation can typically be done by a domain wall generator located in the proximity of the magnet. This makes it possible to form at least one domain wall, in the case where the magnet would have no domain wall.

According to an example, the method for producing the device further comprises, after deposition of the ferromagnetic material in the form of a strip, a formation by lithography and etching notches on opposite edges of the strip, said notches being intended to fix the domain wall during the movement of the domain wall. The wall is typically moved in the longitudinal direction. It extends transversally. The notches formed on either side of the strip locally form a narrowing of the cross-section of the magnet. This makes it possible to block the longitudinal progression of the walls. The walls are thus fixed or anchored at the notches. According to an example, a simple discontinuous variation of cross-section of the strip is formed by lithography and etching. This also makes it possible to fix a domain wall transversally to the strip, at this discontinuous variation.

The distribution of the magnetic domains within the magnet can be modified by moving the domain walls. The application of an electric current in the magnet, in a direction oriented in the longitudinal direction, makes it possible to longitudinally move the walls. The magnet can thus be reinitialised or reconfigured. According to the electric current applied during the initialisation or the reconfiguration of the magnet, it is thus possible to modify the control parameters of the qubits. A programming or reprogramming of the lines or matrices of quantum dots is thus advantageously made possible. The movement of walls can be done by the application of a current or by the combination of an application of a current and of a magnetic field. The latter option advantageously makes it possible to lower the current level necessary for the movements of walls.

According to an example, by choosing to form anchoring points (by notch or by cross-section variation) along the strip with a step of L/2, the walls can be moved via intermediate positions. This makes it possible to consider to configure two consecutive quantum dots in a similar magnetic environment. Moreover, by changing the application direction of the electric current in the magnet, it is also possible to invert the movement direction of the different walls. The device and its reinitialization or reconfiguration method thus advantageously make it possible to obtain a large number of magnet configurations. This advantageously enables a versatile programming of the lines or matrices of quantum dots.

According to an example, the method for reinitialising or reconfiguring the device further comprises a generation of at least one new domain wall, and one second application of an electric current in the magnet, along the longitudinal direction, so as to move the at least one new domain wall in a new position vis-à-vis the first and second quantum dots.

Unless incompatible, it is understood that all of the optional features above can be combined so as to form an embodiment which is not necessarily illustrated or described. Such an embodiment is clearly not excluded from the invention. The features of an aspect of the invention, for example, the device or the method, can be adapted mutatis mutandis to the other aspect of the invention.

It is specified that, in the scope of the present invention, the terms “on”, “surmounts”, “covers”, “underlying”, “opposite” and their equivalents do not necessarily mean “in contact with”. Thus, for example, the deposition of a first layer on a second layer, does not compulsorily mean that the two layers are directly in contact with one another, but means that the first layer covers at least partially the second layer by being either directly in contact with it, or by being separated from it by at least one other layer or at least one other element.

A layer can moreover be composed of several sublayers of one same material or of different materials.

By a substrate, a stack, a layer “with the basis of” a material A, this means a substrate, a stack, a layer comprising this material A only, or this material A and optionally other materials, for example alloy elements and/or doping elements.

Several embodiments of the invention implementing successive steps of the manufacturing method are described below. Unless explicitly mentioned otherwise, the adjective “successive” does not necessarily imply, even if this is generally preferred, that the steps immediately follow one another, intermediate steps being able to separate them.

Moreover, the term “step” means the embodiment of some of the method, and can mean a set of substeps.

Moreover, the term “step” does not compulsorily mean that the actions carried out during a step are simultaneous or immediately successive. Certain actions of a first step can, in particular, be followed by actions linked to a different step, and other actions of the first step can then be resumed. Thus, the term “step” does not necessarily mean single and inseparable actions over time and in the sequence of phases of the method.

A preferably orthonormal system, comprising the axes x, y, z is represented in the accompanying figures. When one single system is represented in one same set of figures, this system is applied to all the figures of this set. The longitudinal direction is taken along x.

The relative terms “on”, “surmounts”, “under”, “underlying”, “interposed” refer to positions taken in the direction z.

The terms “transverse”, “transversally” refer to the plane zy or to a direction of this plane zy. Unless explicitly mentioned otherwise, the thickness, the height and the depth are measured along z.

An element located “in vertical alignment with” or “to the right of” another element means that these two elements are both located in one same plane comprising the direction z, preferably in a plane zy.

A domain wall or magnetic wall is a transition zone between two different magnetisation fields (also called Weiss domains) made of a ferromagnetic material. A magnetic domain, or Weiss domain, is a region of a material, wherein the magnetic moments are oriented in the same direction, the magnetisation is therefore uniform there. The region separating the magnetic domains is called domain wall, wherein the magnetisation progressively or suddenly changes direction. In a magnetic domain, the magnetic moments of each atom are by and large aligned with one another and provide in the same direction. The structure of the magnetic domains is responsible for the magnetic behaviour of the ferromagnetic materials like iron, nickel, cobalt and of their alloys.

The term “wall” is used to describe the interface between two magnetic domains (or Weiss domains). The domain wall marks the passage from one magnetised zone to another. However, this is not necessarily a sudden variation: the change can be made gradually, over a finite distance, with a progressive, continuous or disorganised reversal of the orientation of the magnetic moment. The domain wall can therefore have a certain width in the longitudinal direction x.

According to an example, a so-called Bloch domain wall is a transition zone between two Weiss domains in a material. This is a region where the magnetic moments gradually change from one Weiss domain to another, in the plane of the wall, typically in the plane yz.

Similarly to Bloch walls, Neel walls, which are another type of domain walls, also correspond to a change of direction of magnetisation between two Weiss domains. In this case, the direction of the magnetic moment varies in the magnetisation plane (plane of the thin magnetic layer, typically xy in the figures). Neel walls are preferably formed in the case of thin magnetic layers, which have a thickness less than a critical value, generally of around ten nanometres.

In the scope of the present invention, a domain wall extends mainly along a transverse plane yz and generally has a certain thickness in the longitudinal direction x. Functionally, a domain wall separates two magnetic domains of different magnetisations, in particular, of opposite magnetisations. A domain wall is often attached to a physical anomaly, for example an edge, a notch, a defect. It can, however, be free and move rapidly within a layer or a strip of magnetic material. A domain wall is a zone of finite size which generally comprises a plurality of orientations of magnetic moments distributed mainly continuously, but often chaotically.

By “magnetic field gradient”, this means a variation of the intensity of the magnetic field, in Tesla, in particular in the longitudinal direction x. The direction and the value of the magnetisation of a magnetic domain can be measured by oersted (Oe) or Gauss measurements. Local magnetisation measurements by microscopy by magnetic force with a tip itself magnetised can also make it possible to map the magnetic domains of a magnet.

The longitudinal direction x is carried by a rectilinear axis in the accompanying figures. It can be fully considered to implement the invention for curvilinear geometries. An S-shaped or C-shaped strip can also comprise magnetic domains separated by domain walls, fixed and/or movable along the curvilinear longitudinal direction x. Different strip geometries can therefore be considered without moving away from the principle of the present invention.

Generally, the resonance frequency of a qubit depends on the amplitude of the magnetic field to which it is subjected. In the present invention, the different field amplitudes to which the qubits are subjected are the results between the homogeneous and fixed external field and the oscillating and programmable magnetic field of the magnet (or strip), the oscillations of which depend on the positions of the walls.

In addition, in order to be handled, a qubit must be subjected to a field gradient. In the present invention, the relative position between the qubits and the fields and/or domain walls makes it possible to both obtain the correct field amplitude to reach the different resonance frequencies, and the field gradient for handling qubits.

The option of moving the walls advantageously makes it possible to make the fields of the strip(s) programmable, in order to configure the line or the matrix of qubits as needed.

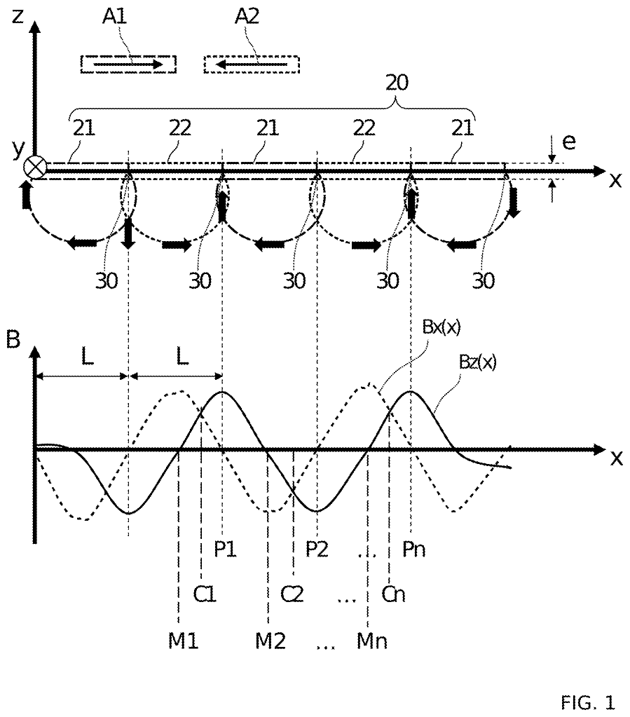

As schematically illustrated in FIG. 1, several magnetic domains 21, 22 are distributed within the magnet 20 alternately in the direction x. These magnetic domains 21, 22 are separated from one another by domain walls 30 such as described above, for example Bloch walls or Neel walls. They typically each have a length L along x, of between and 200 nm, preferably between 40 nm and 100 nm, for example around 50 nm. The thickness e along z of the magnet 20 and of the magnetic domains 21, 22, is typically between 5 nm and 20 nm, preferably around 10 nm. The width along y of the magnet 20 and of the magnetic domains 21, 22, is typically between 20 nm and 200 nm, preferably between and 150 nm.

The magnetic domains 21, 22 each have a magnetisation A1, A2 directed along x. The magnetisation A1 of the magnetic domains 21 has a first direction, for example provided towards the right side of the sheet in FIG. 1, while the magnetisation A2 of the magnetic domains 22 has a second direction, for example provided towards the left side of the sheet in FIG. 1. Each magnetic domain 21, 22 is defined by one single magnetisation A1, A2 having one single direction. The magnet 20 thus has a succession of magnetic domains 21, 22, the magnetisations A1, A2 of which are alternated, opposite one another along x. This produces a magnetic field mainly oriented along x. At the walls 30, field components appear along y and z, while the field component along x is cancelled to change direction. The components of the magnetic field of the magnet 20 thus have an oscillation in the longitudinal direction x. In this example, the oscillation of the components of the field is periodical.

The curves Bz(x) and Bx(x) correspond to the components Bz and Bx of the magnetic field induced by the magnet 20, in the longitudinal direction x. These curves Bz(x) and Bx(x) typically have a period equivalent to the length of two adjacent magnetic domains 21, 22, and are offset from one another by a period quarter along x. Different positions along x correspond to, as a maximum, the oscillation of the magnetic field. The positions Pi (i=1 . . . n) located typically in vertical alignment with the domain walls 30 are thus subjected to a maximum variation of the component Bz of the magnetic field. The positions Mi (i=1 . . . n) located typically at the middle of the magnetic domains 21, 22, projected along z, are thus subjected to a maximum variation of the component Bx of the magnetic field. The positions Ci (i=1 . . . n) located typically at 3/4 of the length L of each magnetic domain 21, 22, i.e. halfway between the positions Pi and Mi, are thus subjected to a maximum variation of the sum of the components Bx+Bz of the magnetic field.

To maximise the differentiation between resonance frequencies of the quantum dots, it is therefore particularly advantageous to have quantum dots facing these positions Pi and/or Mi and/or Ci. In particular, the positions of the quantum dots QDi (i=1 . . . n) for spin qubit electronic device can be advantageously chosen such that they each share one same plane yz with the positions Pi and/or Mi and/or Ci. It also appears that a plurality of positions Pi and/or Mi and/or Ci can suit for the arrangement of quantum dots along x. This makes it possible to obtain a placement tolerance of the quantum dots along the longitudinal direction x, relative to the position of the magnetic domains 21, 22 and/or of the walls 30. The alternance of the magnetisations within the magnet 20, and the oscillations induced in the resulting magnetic field, thus make it possible to maximise the number of positions for which the variation of magnetic field is significant. This makes it possible, in particular, to densify the number of quantum dots along x.

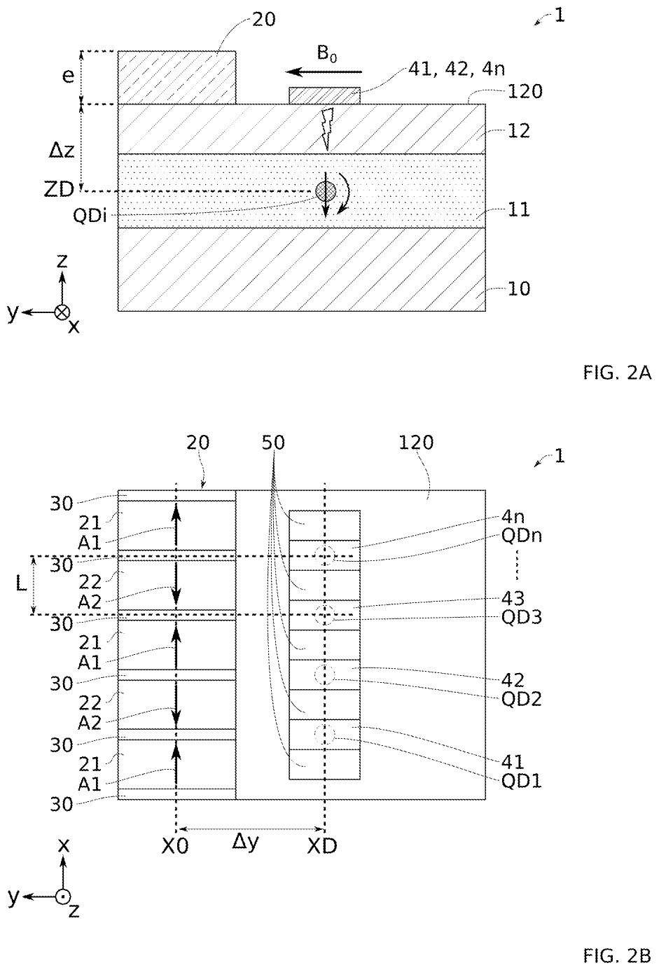

FIGS. 2A, 2B, 3A, 3B, 4A, 4B and 5 illustrate different embodiments of a spin qubit electronic device comprising such a magnet 20 having magnetic domains 21, 22 of alternate magnetisations. As an example, the magnetic domains 21, 22 all have, in this case, a length L along x of around 50 nm, and a magnetisation at 1.5 T/m³. For these embodiments, the quantum dots QDi are positioned facing the domain walls 30, i.e. at the positions Pi along x. Each quantum dot QDi and its corresponding domain wall 30 thus form an intersection with one same plane yz. To be concise, the other configurations, in particular the arrangement of the quantum dots QDi facing the positions Mi or Ci, are not illustrated. These configurations can however be easily defined from the following illustrative examples, and can be fully considered.

FIGS. 2A and 2B respectively illustrate, as a cross-section and as a top view, a first embodiment of the device 1, wherein the magnet 20 in the form of a strip is offset vertically and laterally vis-à-vis the quantum dots QDi (i=1 . . . n).

The quantum dots QDi can be formed conventionally in a silicon-based layer 11 interposed between two silicon oxide-based layers 10, 12. Control gates 4i (i=1 . . . n), configured to generate radiofrequency (RF) waves enabling a transition of the spin state of the quantum dots, are preferably located vertically in vertical alignment with the quantum dots QDi, on the upper face 120 of the layer 12. For each quantum dot, the frequency f of the RF wave which enables the transition of the low energy state to that of higher energy of the spin of an electron is f=(g·μ_{B}·B_{T})/h, where g is the Landé g-factor (g=2 in the case of the electron), μ_{B} is the Bohr magneton (P_{B}=9.27.10-24 J/T), h is the Planck constant and B T the value of the magnetic field received by the quantum dot in question. This resonance frequency f therefore varies according to the magnetic field received by the quantum dot in question. According to a preferred option, each quantum dot QDi is associated with a distinct control gate 4i. Typically, for neighbouring quantum dots, a frequency variation of around 10 MHz makes it possible to control them independently. This frequency variation corresponds to a total magnetic field variation of 26.75 mT. According to a principle of the invention, the total magnetic field variation between two neighbouring quantum dots is maximised by generating an oscillating magnetic field via the magnetic domains 21, 22 of opposite magnetisations A1, A2 within the strip 20.

In this first embodiment, the strip 20 is directly in contact with the upper face 120 of the layer 12. It is located at the side of the control line formed by the gates 4i.

As illustrated in FIG. 2A projected in the plane yz, the vertical offset Δz along z, between the lower face of the strip 20 and an axis ZD passing through the quantum dots QDi, is preferably less than 20 nm, typically for a width of the strip of 150 nm.

As illustrated in FIG. 2B projected in the plane xy, the lateral offset Δy along y, between a central longitudinal axis XO of the strip 20 and an axis XD parallel to XO and passing through the quantum dots QDi, is preferably less than 100 nm, typically for a width of the strip of 150 nm.

As in the magnetic field generated by the magnetic domains 21, 22 is relatively low, typically around 8.95.10⁻²⁴ T, the strip 20 will be advantageously placed closer to the quantum dots QDi.

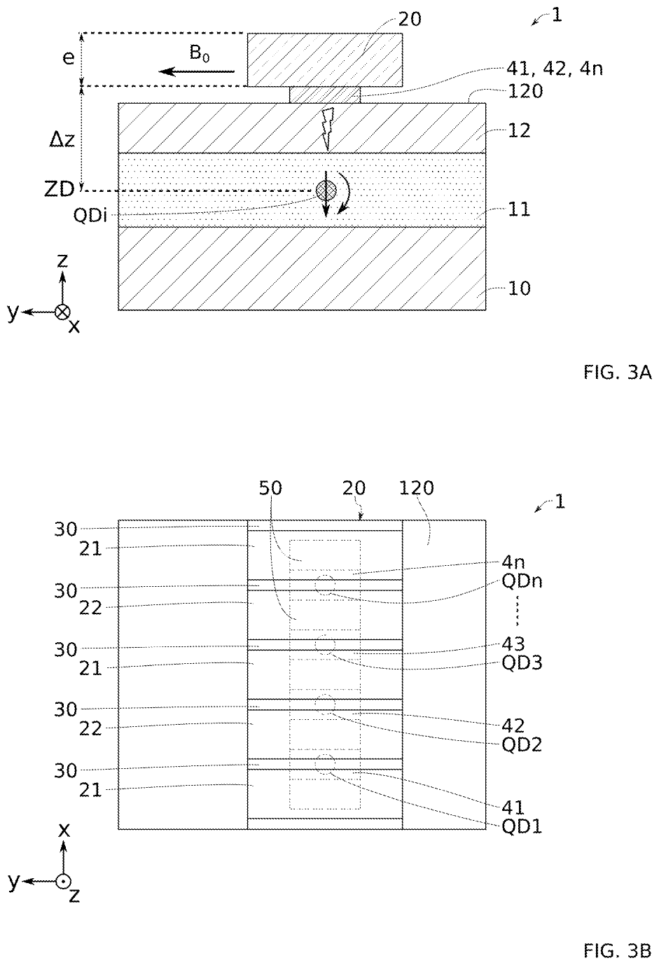

FIGS. 3A and 3B respectively illustrate, as a cross-section and as a top view, a second embodiment of the device 1, wherein the strip 20 is in vertical alignment with the quantum dots QDi (i=1 . . . n), only vertically offset vis-à-vis the quantum dots QDi.

In this second embodiment, the strip 20 is disposed on the control line comprising the gates 4i. The control line is thus interposed between the upper face 120 of the layer 12 and the lower face of the strip 20.

As illustrated in FIG. 3A projected in the plane yz, the vertical offset Δz along z, between the lower face of the strip 20 and the axis ZD passing through the quantum sots QDi, is preferably less than 50 nm, typically for a width of the strip of 50 nm.

As illustrated in FIG. 3B projected in the plane xy, the central longitudinal axis XO of the strip 20 and the axis XD passing through the quantum dots QDi are substantially superposed.

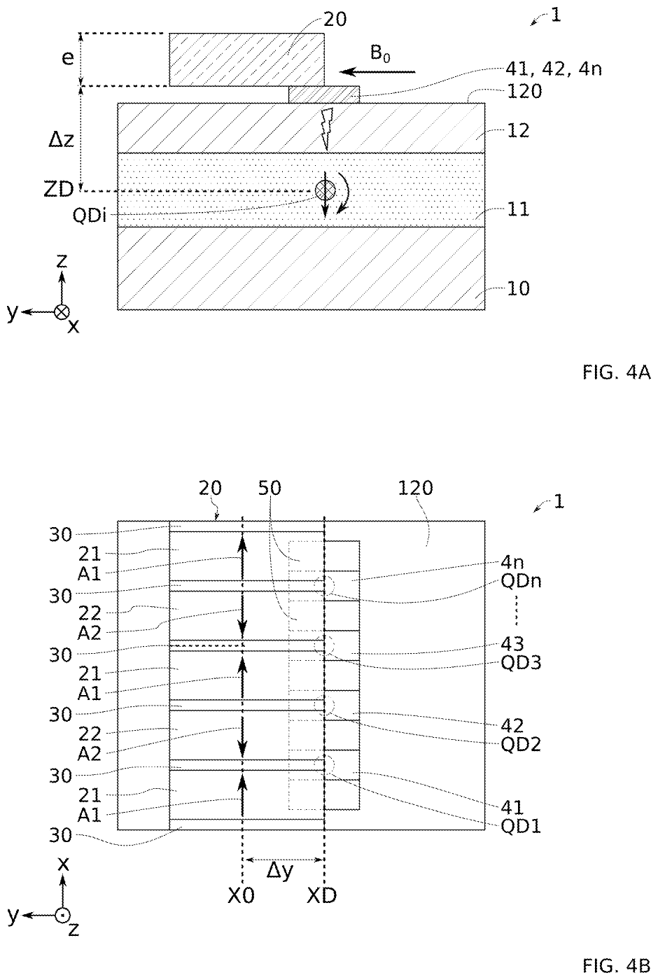

FIGS. 4A and 4B respectively illustrate, as a cross-section and as a top view, a third embodiment of the device 1, wherein the strip 20 partially overlaps the control line comprising the gates 4i. This embodiment is intermediate between the two embodiments described above.

As illustrated in FIG. 4A projected in the plane yz, the strip 20 partially covers the control line. The vertical offset Δz along z, between the lower face of the strip 20 and the axis ZD passing through the quantum dots QDi, is preferably less than 60 nm, typically for a width of the strip of 100 nm.

As illustrated in FIG. 4B projected in the plane xy, the lateral offset Δy along y, between the central longitudinal axis XO of the strip 20 and the axis XD passing through the quantum dots QDi, is preferably less than 10 nm.

The vertical Δz and/or lateral Δy offsets can be increased by typically increasing the width of the strip. In particular, a magnet of large dimensions develops a wider magnetic field, which makes it possible to divert the axes ZD and/or XD passing through the quantum dots QDi.

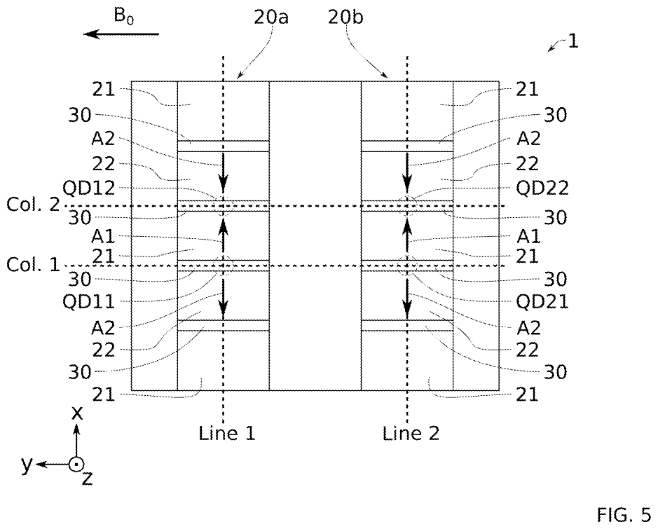

FIG. 5 illustrates, as a top view, another embodiment of the device 1, wherein two strips 20a, 20b are disposed side-by-side along a first line L1 and a second line L2 parallel to one another and directed in the longitudinal direction x. Quantum dots QD11, QD12 are located under the strip 20a, in vertical alignment with the domain walls 30. Quantum dots QD21, QD22 are located under the strip 20b, in vertical alignment with the domain walls 30. Control gates (which cannot be seen) are interposed between each quantum dot and the strip above. The quantum dots QD11, QD12, QD21, QD22 thus form a matrix of quantum dots organised in lines L1, L2 and columns C1, C2. The quantum dot QD11 belongs to the first line L1 and to the first column C1; the quantum dot QD12 belongs to the first line L1 and to the second column C2; the quantum dot QD21 belongs to the second line L2 and to the first column C1; the quantum dot QD22 belongs to the second line L2 and to the second column C2. The resonance frequencies of the columns C1 and C2 are different. Each control gate can be controlled independently. Such a matrix arrangement makes it possible to densify the number of quantum dots which could be controlled individually, for example in view of a quantum calculation application.

In all the configurations described above, the external magnetic field Bo is preferably applied perpendicularly to the strip. This makes it possible to avoid any interaction with the magnetic domains of the strip. The external magnetic field Bo is typically static and constant. Its intensity is typically around one Tesla (T), for example between 0.5 T and 1.5 T. It mainly makes it possible to raise the spin degeneration by Zeeman effect. According to the principle of the invention, this external magnetic field Bo is modulated locally by the magnetic field of the strip, so as to generate variable resonance frequencies for the different quantum dots. The external magnetic field Bo can come from a generator which is external to the device, and independent from it. According to an alternative option, the control gates RF can produce this external magnetic field Bo. This makes it possible to integrate all the control components of the device within said device.

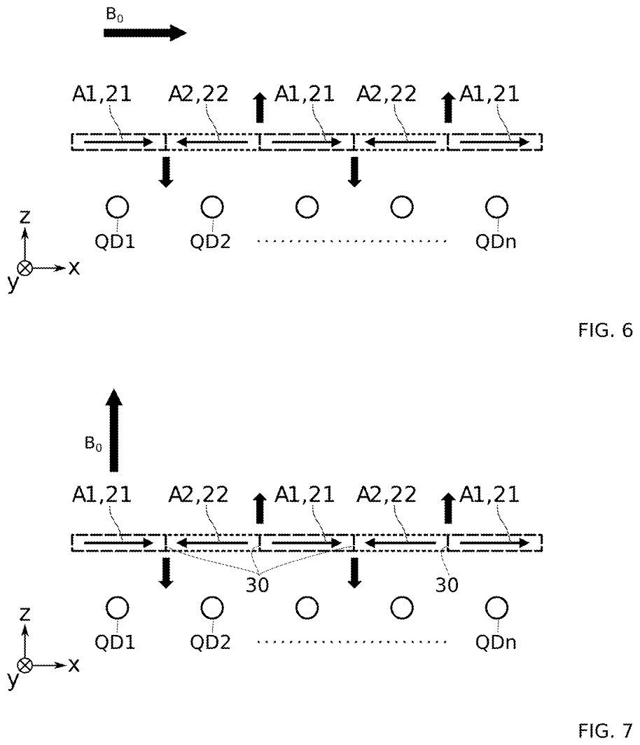

FIG. 6 illustrates an embodiment where the external magnetic field Bo is oriented in the longitudinal direction x, i.e. in the same direction as the magnetic moments of the magnetisations A1, A2 of the magnetic fields 21, 22. The quantum dots QDi are disposed facing the magnetic domains, along z. In this case, the quantum dots receive a result from the magnetic field having maximum amplitude variations, by addition of the macroscopic (Bo) and local fields (generated by the magnet) at the domains 21, 22.

FIG. 7 illustrates another embodiment where the external magnetic field Bo is oriented along z, i.e. perpendicularly to the direction of the magnetic moments of the magnetisations A1, A2 of the magnetic domains 21, 22. The quantum dots QDi are, in this case, facing the domain walls 30, along z. In this case, the quantum dots receive a result from the magnetic field having maximum amplitude variations, by addition of the macroscopic (Bo) and local fields (generated by the magnet) at the walls 30.

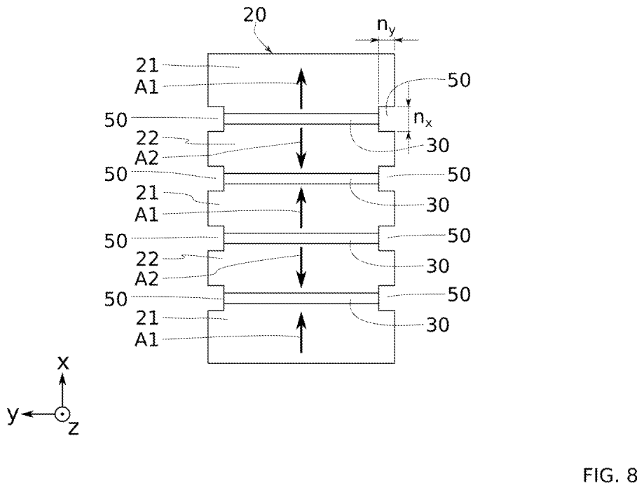

FIG. 8 illustrates an advantageous embodiment of the strip 20, wherein the positions of the domain walls 30 are imposed by notches 50 made in the strip 20. The notches 50 typically form a narrowing of the cross-section of the strip 20. They can be rectangular, for example of dimensions nₓ along x of between 15 and 30 nm, and n_{y} along y of between 5 and 20 nm. A pair of notches 50 on either side of the strip 20 typically makes it possible to block the progression of a wall 30 along x, as explained in the document, “Physical Review B, 79, 094430 (2009)”. The positions of the domain walls 30 can thus be accurately controlled thanks to the presence of notches 50 distributed along the longitudinal edges of the strip 20.

The present invention also relates to a method for producing a device 1 such as described above.

The quantum dots are first formed in a known manner in a semi-conductive layer 11, for example silicon-based or of material III-V, along a longitudinal axis XD with preferably a separation distance L between each quantum dot. A dielectric layer 12, for example, SiO²-based, can then be formed or deposited on the layer 11. Control gates are then formed conventionally, typically by lithography, in vertical alignment with the quantum dots. At this stage, qubits are formed from a metal oxide semiconductor field-effect transistor (MOSFET) architecture. Other architectures, for example based on a two-dimensional electron gas, are also possible.

The magnet can then be formed during so-called BEOL (back end of line) steps of microelectronic technologies, by deposition of one or more ferromagnetic materials. Such materials commonly used in the microelectronics industry, are typically Fe-, Co-, B- or Ni-based, or alloys of these metals (for example, CoFe, CoFeB). They preferably have a Curie temperature greater than 1000° C. These ferromagnetic materials can be deposited by physical vapour deposition (PVD), for example, by cathode spraying from targets of the desired alloy or by joint spraying from targets of metals which constitute the alloy. They can be shaped by lithography, for example, by electronic (electron beam) lithography, followed by a known so-called “lift-off” step, or an ion-type etching by ion beam etching (IBE). This makes it possible to structure the ferromagnetic materials typically in the form of a strip comprising notches spaced apart along x by a distance L or nL, n being a non-zero natural integer. In the embodiment illustrated in FIG. 8, the notches 50 are typically “retracting”. They can alternatively be of the “exiting” form. According to another option, the structuring of the strip by lithography can be configured so as to obtain a succession of different magnetic domains along y, with sudden variations of cross-section between two adjacent magnetic domains. The width of this strip is preferably around 50 to 150 nm. The thickness of this strip is preferably around 10 nm. Different examples of CoFe- or Ni₈₀Fe₂₀-based ferromagnetic strip are, for example, respectively described in the documents, “Tsoi et al, Appl. Phys. Lett., Vol. 8, No. 13, 2003” and “Malinowski et al, J. Phys. D: Appl. Phys., 44, 384005, 2011”.

After structuring of the strip, an electric current is applied longitudinally between the two ends of the strip. This electric current of around 10⁶ to 10⁷ A/cm² makes it possible to orient the magnetic domains and to move the domain walls to the anchoring points formed by the notches.

According to an option not illustrated, a domain wall generator is formed in the proximity or at an end of the strip. Such a wall generator can be presented in the form of a ferromagnetic material-based injection structure of large dimensions contiguous with one of the ends of the magnet or of the strip. Such a structure is, for example, described in the document, “R. P. Cowburn, Journal of Applied Physics 91, 6949 (2002)”. This makes it possible to initiate and/or facilitate the creation of the domain walls.

According to an advantageous option, the strip can be reconfigured by applying an electric current longitudinally. Certain domain walls can, for example, be moved and/or stacked. This makes it possible to extend certain magnetic domains and to reduce the number of domain walls. New domain walls can be created by the domain wall generator, then moved again. The application of a current in the strip in a first direction moves the walls in this same first direction. All the walls are preferably moved during the application of this current. The application of an electric current in a direction opposite the first direction typically makes it possible to change the movement direction of the walls. It is thus possible to divert a magnetisation magnetic domain A2 to a given quantum dot, which was previously associated with a magnetisation magnetic domain A1. The resonance frequencies of the different quantum dots can thus be modified.

The device according to the invention can thus be reconfigured in different ways, for example, according to the targeted applications.

The invention is not limited to the embodiments described above. In particular, the number of magnetic domains, of quantum dots and of domain walls can vary according to the applications. The magnet can also be associated with different architectures making it possible to form qubits. The invention can also be implemented for spin qubits, the charge carriers of which are holes.

1. An electronic device comprising at least:
one first quantum dot one second quantum dot disposed along a longitudinal direction, configured to each have two opposite spin states in a presence of an external magnetic field,
one first control gate associated with the first quantum dot,
one second control gate associated with the second quantum dot, and
one magnet configured to locally generate a magnetic field gradient between the first and second quantum dots, such that the first and second quantum dots respectively have first and second resonance frequencies which are different from one another,
wherein the magnet comprises at least one first magnetic domain and one second magnetic domain distributed along the longitudinal direction and separated by at least one domain wall, said first and second magnetic domains respectively have a first magnetisation and a second magnetisation of opposite directions in the longitudinal direction, so as to locally generate said magnetic field gradient between the first and second quantum dots.

2. The device according to claim 1 comprising N quantum dots distributed along the longitudinal direction and a plurality of control gates associated with the N quantum dots, wherein
the magnet comprises a number M of first and second magnetic domains distributed along the longitudinal direction, alternate from one another, and separated by M−1 domain walls, and
two adjacent quantum dots are separated by a distance L in the longitudinal direction, and wherein a magnetic domain taken from among the first and second magnetic domains has a dimension n·L in the longitudinal direction, with n being a non-zero natural integer such that 1≤n≤N−M+1.

3. The device according to claim 1, wherein the magnet is presented in a fore of a strip, and wherein the at least one domain wall is transversally fixed to the strip by a discontinuous variation of a cross-section of the strip.

4. The device according to claim 1, further comprising a domain wall generator at a border of the magnet.

5. The device according to claim 1 comprising N quantum dots occupying N positions P1 to PN distributed along the longitudinal direction, N gates associated with said N quantum dots, wherein the magnet comprises M magnetic domains, M≤N+1, having opposite alternating magnetisations and separated by M−1 domain walls, the M−1 walls respectively comprising M−1 transverse planes in the longitudinal direction, each passing through a position taken from among the positions P1 to PN of the N quantum dots.

6. The device according to claim 1 comprising N quantum dots regularly separated by a distance L in the longitudinal direction, and N gates associated with said N quantum dots, wherein the magnet comprises N magnetic domains of dimension substantially equal to L in the longitudinal direction (x), having opposite alternating magnetisations and separated by N−1 domain walls, the N quantum dots being distributed along the longitudinal direction facing and corresponding to the N magnetic domains, each quantum dot occupying, in the longitudinal direction, a position located at 3/4L vis-à-vis an end of the corresponding magnetic domain.

7. The device according to claim 1 comprising N quantum dots regularly separated by a distance L in the longitudinal direction, and N gates associated with said N quantum dots, wherein the magnet comprises N magnetic domains of dimension substantially equal to L in the longitudinal direction, having opposite alternating magnetisations and separated by N−1 domain walls, the N quantum dots (QDi) being distributed along the longitudinal direction (x) facing and corresponding to the N magnetic domains, each quantum dot occupying, in the longitudinal direction, a position located at L/2 vis-à-vis an end of the corresponding magnetic domain.

8. The device according to claim 1, comprising at least one first line and one second line parallel to one another and directed in the longitudinal direction, each line comprising at least two quantum dots and two control gates, each respectively associated with one of said quantum dots, the device further comprising at least one first magnet and one second magnet respectively associated with the first and second lines, each magnet comprising at least the first and second magnetic domains distributed along the longitudinal direction and separated by a domain wall, the first and second magnetic domains respectively having the first and second magnetisations of opposite directions in the longitudinal direction, the first magnet being disposed parallel to the first line and the second magnet being disposed parallel to the second line, so as to locally generate a first magnetic field gradient between first and second ones of the quantum dots of the first line, and a second magnetic field gradient between first and second ones of the quantum dots of the second line.

9. The device according to claim 8, wherein the first and second magnetisations of the first and second magnetic domains of the first magnet respectively having a same direction as the first and second magnetisations of the first and second magnetic domains of the second magnet, at same positions in the longitudinal direction along the first and second lines.

10. A system comprising at least one device according to claim 1, the system being taken from among: a computer or a quantum accelerator, and a quantum router.

11. A method for producing the device according to claim 1 comprising:
forming the first and second quantum dots,
forming the first and second control gates associated with said first and second quantum dots, and
forming the magnet by carrying out:
depositing a ferromagnetic material, and
moving the domain wall within the ferromagnetic material so as to form the first and second magnetic domains, by applying an electric current along the longitudinal direction.

12. The method according to claim 11, further comprising, before the movement of the domain wall, generating at least one domain wall within the ferromagnetic material.

13. The method according to claim 11 further comprising, after depositing the ferromagnetic material in the form of a strip, forming, by lithography and etching, notches on opposite edges of the strip, the notches being configured to fix the domain wall during the movement of the domain wall.

14. A method for reinitialising a device according to claim 1 comprising applying a first electric current in the magnet, along the longitudinal direction, so as to move the at least one domain wall.

15. The re-initialisation method according to claim 14, further comprising generating at least one new domain wall, and applying a second electric current in the magnet, along the longitudinal direction, so as to move the at least one new domain wall into a new position vis-à-vis the first and second quantum dots.
